(19) United States
(12) Patent Application Publication
(10) Pub. No.: US 2007/0279862 A1
(43) Pub. Date: Dec. 6, 2007

(54) Heat-Dissipating Structure For Lamp

(76) Inventor: Jia-Hao Li, Sindian City (TW)

Correspondence Address: HDSL, 4331 STEVENS BATTLE LANE, FAIRFAX, VA, 22033, US

(21) Appl. No.: 11/422,377

(22) Filed: Jun. 6, 2006

(51) Int. Cl. H05K 7/20

(52) U.S. Cl. 361/692

(57) ABSTRACT

A heat-dissipating structure includes a heat-dissipating body and a heat pipe. The heat-dissipating body includes a first cylinder and a second cylinder provided within the first cylinder. A plurality of heat-dissipating pieces is further connected between the first cylinder and the second cylinder. A heat-dissipating path is formed between each heat-dissipating piece. The heat pipe is accommodated in the second cylinder and tightly connected thereto. With the heat conduction of the heat pipe, the heat generated by the operation of the LED lamp is absorbed and conducted to the second cylinder. Then, the heat is dissipated uniformly to the plurality of heat-dissipating pieces and the first cylinder. With the above arrangement, the present invention achieves the desired heat-dissipating effect and it is easy to grip and assemble the heat-dissipating body.

### BACKGROUND OF THE INVENTION

1. Field of the Invention

The present invention relates to a heat-dissipating structure, and in particular to a heat-dissipating structure suitable for a LED lamp.

2. Description of Prior Art

With the development of novel materials and techniques, light-emitting diodes (LED) have been widely used in various kinds of fields because they are compact in size, short in response time and do not generate any pollution. At earlier stage, the intensity of the light-emitting diodes are insufficient, however, the recent development of the LED has made a great advance in their intensity. Therefore, the LEDs tend to replace the conventional illuminating elements.

Especially, with the development of high-power light-emitting diodes, their material needs to consume larger amount of electric current, and thus generates more heat. In order to make the illuminating device having light-emitting diodes to operate under a suitable working temperature, a heat-dissipating structure is provided on the illuminating device, which has recently become a feasible measure to achieve a desired heat-dissipating effect.

A conventional heat-dissipating structure for a LED lamp is shown in FIG. 1. The heat-dissipating structure mainly comprises a heat-dissipating body 10a and a heat pipe 12a. The heat-dissipating body 10a has a hollow pipe body 101a for accommodating the heat pipe 12a. Further, the outer surface of the pipe body 101a is provided with a plurality of heat-dissipating pieces 102a in a radial arrangement. The heat pipe 12a has a working fluid and the capillary structure therein. Therefore, after the heat pipe 12a absorbs the heat generated by the light-emitting diodes, the generated heat can be transferred by the inner working fluid and the capillary structure and dissipated to the heat-dissipating body 10a. Then, with the plurality of heat-dissipating pieces 102a, the heat can be dissipated to the outside to achieve a desired heat-dissipating effect.

In the above-mentioned heat-dissipating structure, the plurality of heat-dissipating pieces 102a provided on the heat-dissipating body 10a is vertically connected to the outer surface of the hollow pipe body 101a in a radial arrangement. Although such arrangement of the heat-dissipating pieces 102a is helpful to increase the area for heat dissipation, when in assembling or conveying, it is most suitable for a user to grip the heat-dissipating body 10a. However, owing to the radial arrangement of the plurality of heat-dissipating pieces 102a, it is very inconvenient for the user to grip the heat-dissipating body, and even the user may get hurt. Therefore, it is necessary for the conventional heat-dissipating structure to overcome the above drawback.

In view of the above, the inventor proposes the present invention to overcome the above problems based on his expert experiences and deliberate researches.

### SUMMARY OF THE INVENTION

In view of the above drawback, the present invention is to provide a heat-dissipating structure for a lamp, which has two cylinders. The heat-dissipating body is designed to have a cylindrical structure to not only increase the area for heat dissipation but also facilitate the user to grip the heat-dissipating body in assembling or conveying the lamp, thereby to enhance the convenience and comfortable feeling in using.

The present invention provides a heat-dissipating structure for a lamp, which comprises a heat-dissipating body and a heat pipe. The heat-dissipating body includes a first cylinder and a second cylinder provided within the first cylinder. A plurality of heat-dissipating pieces is further connected between the first cylinder and the second cylinder. The plurality of heat-dissipating pieces is formed into a radial arrangement. A heat-dissipating path is formed between each heat-dissipating piece. The heat pipe is accommodated in the second cylinder and tightly connected thereto. With the heat conduction of the heat pipe, the heat generated by the operation of the LED lamp is absorbed and conducted to the second cylinder. Then, the heat is dissipated uniformly to the plurality of heat-dissipating pieces and the first cylinder. With the above arrangement, the present invention achieves the desired heat-dissipating effect and it is easy to grip and assemble the heat-dissipating body.

### BRIEF DESCRIPTION OF THE DRAWINGS

FIG. 1 is a perspective view showing the structure of the prior art;

FIG. 2 is an exploded perspective view showing the structure of the present invention;

FIG. 3 is an assembled view showing that the heat-dissipating structure of the present invention is applied to a lamp structure;

FIG. 4 is a schematic view showing the structure of another embodiment of the present invention;

FIG. 5 is a schematic view showing the structure of still another embodiment of the present invention;

FIG. 6 is a cross-sectional view showing the structure of the heat-dissipating body of another embodiment of the present invention;

FIG. 7 is a cross-sectional view showing the structure of the first cylinder of another embodiment of the present invention; and

FIG. 8 is a cross-sectional view showing the structure of the heat-dissipating body of still another embodiment of the present invention.

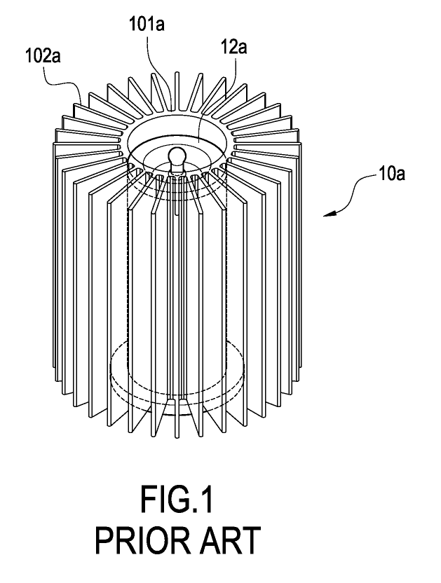

### DETAILED DESCRIPTION OF THE INVENTION

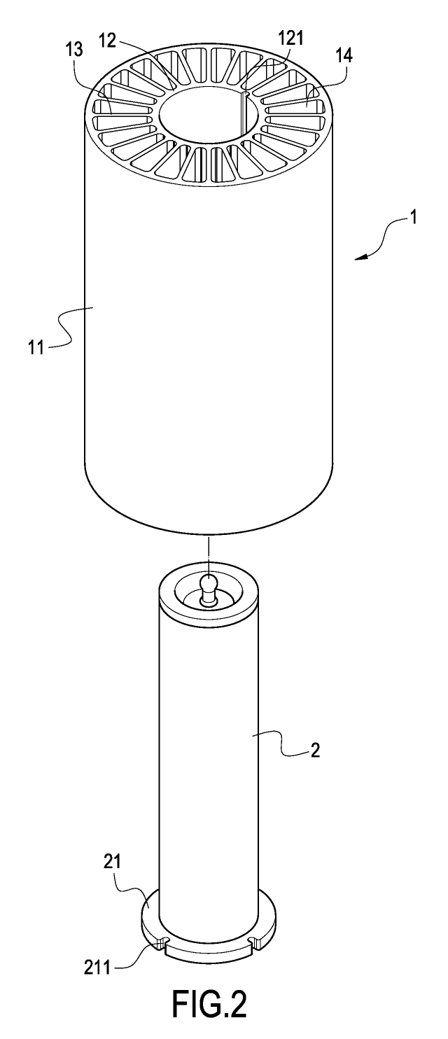

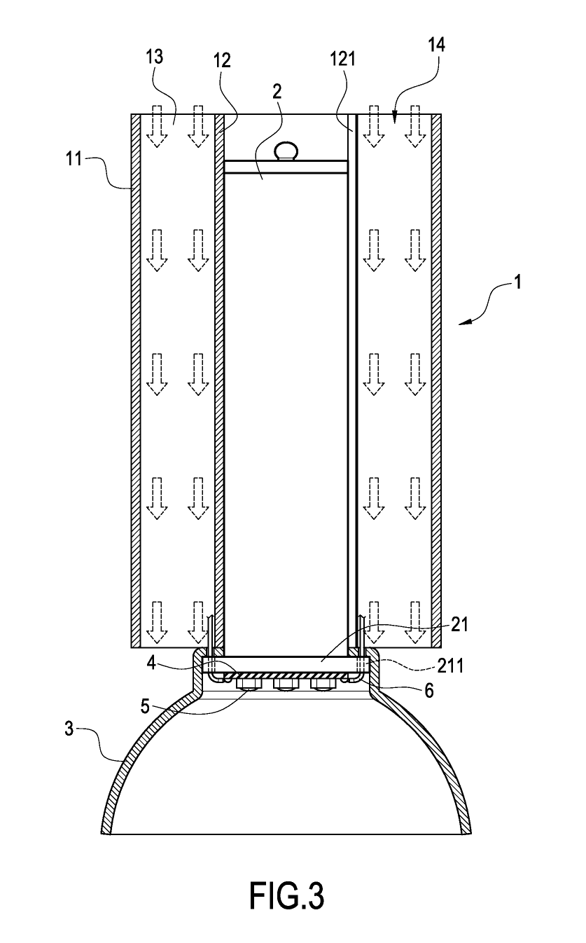

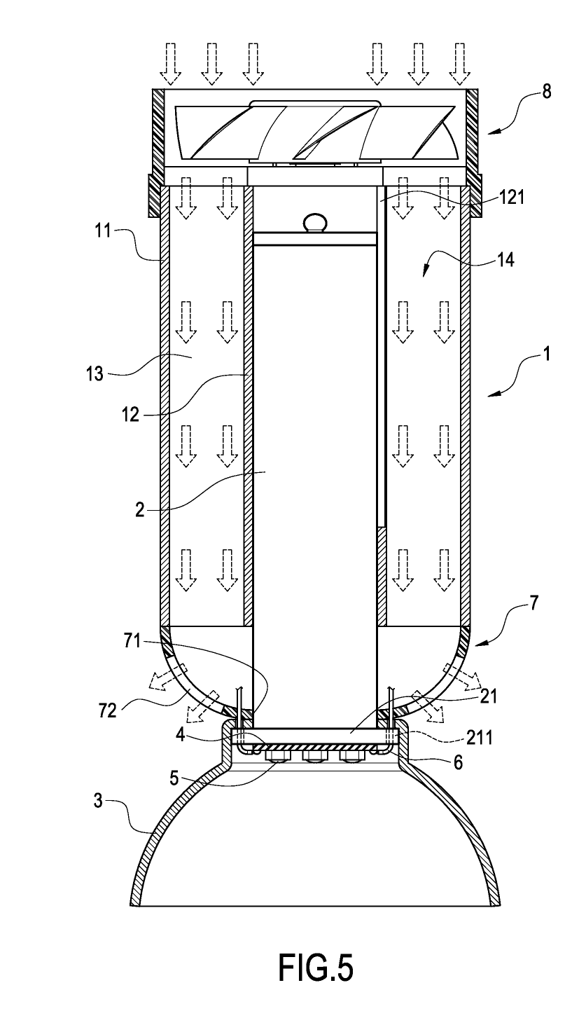

With reference to FIG. 2, it is an exploded perspective view showing the structure of the present invention. It can be seen from the drawing that the heat-dissipating structure of the present invention mainly comprises a heat-dissipating body 1 and at least one heat pipe 2. The heat-dissipating body is made of materials having high heat conductivity. The heat-dissipating body further comprises a first cylinder 11 and at least a second cylinder 12 (one shown in the drawing). The cross section of the first cylinder 11 is formed into a circular shape. The second cylinder 12 is provided within the first cylinder 11 for accommodating the heat pipe 2. A plurality of heat-dissipating pieces 3 is connected between the first cylinder 11 and the second cylinder 12. As seen from the top, the plurality of heat-dissipating pieces 13 is formed into a radial arrangement. Further, a heat-dissipating path 14 is formed between each heat-dissipating piece 13 for allowing the air to flow therein. The periphery of the second cylinder 12 is provided with at least one solder inlet 121 (one shown in the drawing) for injecting the solder. The solder inlet 121 is a closed inlet without penetrating through the wall face of the second cylinder 12 but penetrating the heat-dissipating body 1 along the axial direction of the second cylinder 12 (as shown in the cross-section view in FIG. 3). Alternatively, as shown in FIG. 5, a portion of the solder inlet 121 can be provided at the periphery of the second cylinder 12. Further, the plurality of heat-dissipating pieces 13 connected between the first cylinder 11 and the second cylinder 12 can be integrally formed. The heat pipe 2 is accommodated in the second cylinder 12 and tightly connected thereto. The heat pipe 2 has a working fluid and the capillary structure therein for heat conduction, which is conventional and the description thereof is omitted. The front end of the heat pipe 2 is further provided with a heat-conducting seat 21. Both sides of the heat-conducting seat 21 are provided with a plurality of grooves 211. In the present embodiment, the number of the grooves is two.

With reference to FIG. 3, it is an assembled view showing that the heat-dissipating structure of the present invention is applied to a lamp structure. As shown in the drawing, the lamp structure comprises a lamp cover 3, a base plate 4 and a plurality of light-emitting elements 5. The bottom of the lamp cover 3 has a through hole 31, so that the heat pipe 2 can penetrate through the through hole. The heat-conducting seat 21 on the heat pipe 2 is accommodated in the bottom of the lamp cover 3. The base plate 4 is connected on the heat-conducting seat 21. Finally, the plurality of light-emitting elements 5 (light-emitting diodes in the present embodiment) are provided on the base plate 4 and electrically connected with each other. Leads 6 are connected to a power supply via the grooves 211. When the electricity is supplied to the light-emitting elements 5 via the leads 6, the heat generated by the operation of the plurality of light-emitting elements 5 is absorbed by the heat-conducting seat 21 adhering to the base plate 4, and then transferred to the heat pipe 2. With the heat exchange caused by the capillary structure and the working fluid within the heat pipe 2, the heat absorbed by the heat-conducting seat 21 can be transferred to the second cylinder 12 tightly connected to the heat pipe 2, and then dissipated uniformly to the plurality of heat-dissipating pieces 13, thereby to perform the heat dissipation. In addition to the heat-dissipating area formed by the plurality of heat-dissipating pieces 13 on the heat-dissipating body 1, the heat dissipation can be also performed by the heat exchange with the air flowing in the heat-dissipating path 14. The air having absorbed the heat flows to the outside via the outlets on one side of the heat-dissipating body 1. As shown in the drawing, the direction of the arrow is the direction of airflow. In this way, the heat dissipation can be completed. Further, the generated heat can be transferred to the first cylinder 11 via a plurality of heat-dissipating pieces 13 and is directly heat exchanged with the outside air, thereby to increase the efficiency in the heat dissipation.

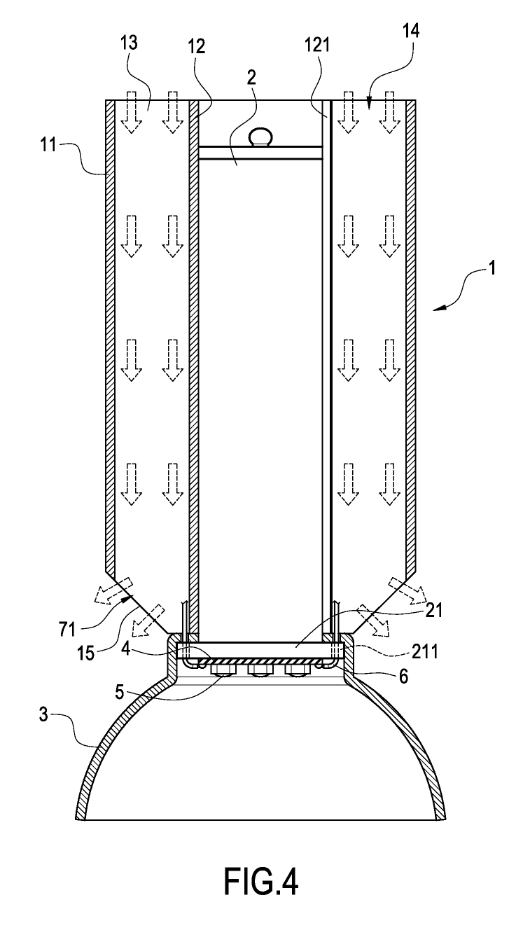

With reference to FIG. 4, it shows another embodiment of the heat-dissipating body 1 of the present invention. It can be seen from the drawing that, in order to make the air within the heat-dissipating body 1 to rapidly flow to the outside to enhance the heat-dissipating effect of air-cooling action, one end of the first cylinder 11 of the heat-dissipating body 1 adjacent to the lamp cover 2 has an annular chamfer 15. The annular chamfer is used to enlarge the substantial outlet (or inlet) for the air within the heat-dissipating body 1, thereby to facilitate the flowing of the air within the heat-dissipating body 1. Further, as shown in FIG. 5, a cover body 7 is provided between the heat-dissipating body 1 and the lamp cover 3. The cover body 7 is formed into a semi-circular shape. The bottom of the cover body has an open hole 71, so that the heat pipe 2 penetrates through the open hole. The open hole 71 is correspondingly connected to the through hole 31 on the bottom of the lamp cover 3. After the heat pipe 2 penetrates into the lamp cover 3, it can penetrate into the cover body 7 with the cover body 7 sandwiched between the lamp cover 3 and the heat-dissipating body 1. The periphery of the cover body 7 is provided with a plurality of openings 72. Further, the other end of the heat-dissipating body 1 is provided with a fan assembly 8. With the blowing action of the fan assembly 8 from the other end, the air within the heat-dissipating body 1 can be forced to flow rapidly. Also, the air flowing in the heat-dissipating body 1 exhausts to the outside via the plurality of openings 72. Alternatively, if the fan assembly 8 is not provided, the annular openings 72 can be used as the inlets (or outlets) for the airflow, thereby to achieve the heat dissipation of the interior of the heat-dissipating body 1.

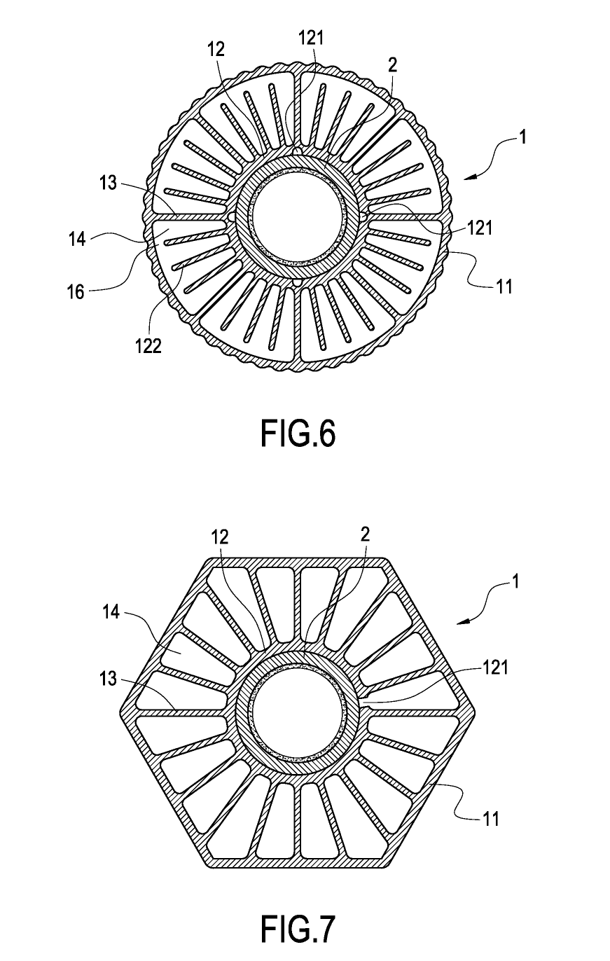

Alternatively, as shown in FIG. 6, the structure of the plurality of heat-dissipating pieces 12 within the heat-dissipating body 1 can be provided to connect on the outer surface of the second cylinder 12. The plurality of heat-dissipating fins 122 is integrally formed with the second cylinder 12. A gap 16 is formed between the other end of the heat-dissipating fin 122 and the first cylinder 11. The outer surface of the first cylinder 11 is formed into a waved shape to increase the area for heat dissipation. Further, multiple solder inlets 121 can be arranged at the periphery of the second cylinder 12. Further, in addition to the circular shape as shown in the above embodiment, the cross section of the first cylinder 11 of the heat-dissipating body 1 can be designed as a polygon. For example, as shown in FIG. 7, the cross section of the first cylinder 11 is formed into a hexagon. Further, the solder inlet 121 on the periphery of the second cylinder 12 can be designed as an open inlet for penetrating through the wall face of the second cylinder. Also, the solder inlet can penetrate the heat-dissipating body 1 along the axial direction of the second cylinder 12 or a portion of the solder inlet is arranged in the heat-dissipating body.

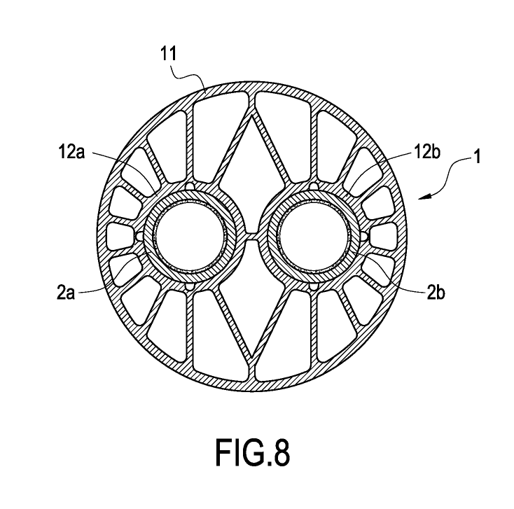

In the above-mentioned structure of the heat-dissipating body 1, as shown in FIG. 8, the interior of the first cylinder 11 can be alternatively provided with a plurality of second cylinders 12 (12a and 12b shown in the drawing). The heat pipes 2 (2a and 2b shown in the drawing) are provided within the second cylinders 12. A heat-conducting medium 131 is injected via the solder inlet 121 to improve the heat-dissipating efficiency between the heat pipe 2 and the second cylinder 12.

Although the present invention has been described with reference to the foregoing preferred embodiments, it will be understood that the invention is not limited to the details thereof. Various equivalent variations and modifications can still be occurred to those skilled in this art in view of the teachings of the present invention. Thus, all such variations and equivalent modifications are also embraced within the scope of the invention as defined in the appended claims.

What is claimed is:

1. A heat-dissipating structure for a lamp for performing the heat dissipation of a LED lamp, comprising:
a heat-dissipating body having a first cylinder and at least one second cylinder provided within the first cylinder, a plurality of heat-dissipating pieces connected between the first cylinder and the second cylinder, a heat-dissipating path formed between every two heat-dissipating pieces; and
a heat pipe penetrating into the second cylinder of the heat-dissipating body and connected thereto.

2. The heat-dissipating structure for a lamp according to claim 1, wherein an outer surface of the first cylinder is formed into a waved shape.

3. The heat-dissipating structure for a lamp according to claim 1, wherein one end of the first cylinder has an annular chamfer.

4. The heat-dissipating structure for a lamp according to claim 1, wherein the first cylinder is provided with a plurality of second cylinders therein.

5. The heat-dissipating structure for a lamp according to claim 1, wherein a periphery of the second cylinder is provided with at least one solder inlet.

6. The heat-dissipating structure for a lamp according to claim 5, wherein the solder inlet is closed.

7. The heat-dissipating structure for a lamp according to claim 5, wherein the solder inlet is open.

8. The heat-dissipating structure for a lamp according to claim 5, wherein a portion of the solder inlet is provided along an axial direction of the second cylinder.

9. The heat-dissipating structure for a lamp according to claim 5, wherein the solder inlet penetrates through the heat-dissipating body along an axial direction of the second cylinder.

10. The heat-dissipating structure for a lamp according to claim 1, wherein a cross section of the heat-dissipating pieces is formed into a radial arrangement and the heat-dissipating pieces are connected between the first cylinder and the second cylinder.

11. The heat-dissipating structure for a lamp according to claim 1, wherein the heat-dissipating path is further provided with a plurality of heat-dissipating fins therein.

12. The heat-dissipating structure for a lamp according to claim 11, wherein each end of the plurality of heat-dissipating fin is connected to an outer surface of the second cylinder.

13. The heat-dissipating structure for a lamp according to claim 1, wherein the first cylinder, the second cylinder and the heat-dissipating pieces are integrally formed.

14. The heat-dissipating structure for a lamp according to claim 1, further comprising a fan assembly connected to one end of the heat-dissipating body.

15. The heat-dissipating structure for a lamp according to claim 1, wherein the other end of the heat-dissipating body is further connected to a cover body.

16. The heat-dissipating structure for a lamp according to claim 15, wherein a periphery of the cover body is provided with a plurality of openings.

17. The heat-dissipating structure for a lamp according to claim 15, wherein a bottom of the cover body is provided with an open hole.

18. The heat-dissipating structure for a lamp according to claim 1, wherein one end of the heat pipe is connected to a heat-conducting seat.
